(19) United States
(12) Patent Application Publication
(10) Pub. No.: US 2025/0377435 A1
(43) Pub. Date: Dec. 11, 2025

(54) RF Bridge Device

(71) Applicant: SEE ID Inc., Las Vegas, NV (US)

(72) Inventors: Edmund Nabrotzky, Pittsford, NY (US); Vijayan Nambiar, Shirley, MA (US); Anthony Bouzakis, London (GB)

(21) Appl. No.: 19/231,183

(22) Filed: Jun. 6, 2025

Related U.S. Application Data
(60) Provisional application No. 63/657,029, filed on Jun. 6, 2024.

(51) Int. Cl. G01S 5/02; G01D 5/14; H01Q 9/04; H01Q 9/30; H05K 5/02; H05K 7/14

(52) U.S. Cl. CPC G01S 5/0294; G01D 5/145; G01S 5/0268; H01Q 9/0492; H01Q 9/30; H05K 5/0217; H05K 7/1427

(57) ABSTRACT

A low power, battery operated electronic device capable of traveling through a process while gathering and locating radio frequency (“RF”) signals from a plurality of other bridges and transponders. The bridge device provides many advantages due to its construction, function, and RF performance. The device has batteries mounted on one side of the assembly which is in contrast to the traditional over or under location common in the industry. Accordingly, a unique compensating antenna is configured to be mounted beside a battery tube even while on metal and rotated to maximize gain in a targeted direction. This rotation also allows operators to visually “flag” issues or signal the system when intervention is needed.

### CROSS-REFERENCE TO RELATED APPLICATION

The present invention claims priority benefit to U.S. Provisional Patent Application No. 63/657,029 entitled “RF Bridge Device” filed on Jun. 6, 2024, which is incorporated herein by reference.

### TECHNICAL FIELD

The present invention relates generally to the field of mobile electronic devices capable of traveling through a system while gathering and locating radio frequency (“RF”) signals from a plurality of other bridges and transponders, and more particularly to a battery powered RF bridge device configured for use in such a system.

### BACKGROUND ART

It is known in the industry to mount batteries over or under an antenna in an electronic device for use as a mobile tracker.

### BRIEF SUMMARY OF THE INVENTION

With parenthetical reference to the corresponding parts, portions or surfaces of the disclosed embodiment, merely for the purposes of illustration and not by way of limitation, the present invention provides a low power, battery operated electronic device capable of being tracked while traveling through a process while also gathering and locating radio frequency (“RF”) signals from a plurality of other bridges and transponders. The RF bridge device (9) provides many advantages due to its construction, function, and RF performance. The device (9) has batteries (158, 161) mounted on one side of the device (9) which is in contrast to the traditional over or under location common in the industry. Accordingly, a unique compensating antenna (42) is configured to be mounted beside a battery tube (10) even while on metal and rotated to maximize gain in a targeted direction. This rotation also allows operators to visually “flag” issues or signal the system when intervention is needed. The device (9) may incorporate two radios, enabling projection of a low frequency power wave to illuminate passive transponders via one radio while simultaneously gathering the beacons that they generate on another higher frequency radio. The microwave antenna (42) is a circularly polarized monopole that is capable of changing the shape of the radiation pattern based on the orientation. When it is disposed against a reflective substrate, (i.e., metal) it functions as if it is a patch antenna. This configuration is a unique implementation of beam forming technology.

The battery tube (10) increases durability and safety by implementing a “crush zone” design. The body of the battery tube (10) is also configured to enable a snap-lock bracket (30) to keep the device (9) in the correct orientation. Channels in the body also enable secure placement of a dynamic contact plate (14, 143) to enable different battery configurations without changing the main design or construction of the assembly. The apertures around the plate (14, 143) enable optional wiring and accessories to be attached to the end of the tube (10) in a unique manner.

In one embodiment, a radio frequency bridge device (9) is provided for use with an object to be tracked. The bridge device (9) includes a tube (10) configured to receive one or more batteries (158, 161). The tube (10) has a first opening (16) at a first end (13) and a second opening (22) at a second end (19). The second end (19) is disposed opposite from the first end (13). The tube (10) has a body portion with an outer wall (12).

An enclosure (27) extends outward from the outer wall (12) of the tube (10).

A printed circuit board assembly (29) is mounted in the enclosure (27).

An antenna (42) is disposed on the printed circuit board assembly (29).

A bracket (30) is configured to mount to the surface of the object to be tracked. The bracket (30) is configured such that the tube (10) rotates inside the bracket (30) between a first position and a second position. In the first position a bottom surface of the enclosure (27) is oriented parallel and facing the surface of the object. In a second position the enclosure (27) is disposed substantially perpendicular to the surface of the object.

In another aspect, the bracket (30) further comprises a tooth (83) that is configured to hold the bridge device (9) down relative to the surface of the object in a standard area sweep positions in a first position and is configured to hold the bridge device (9) in a perpendicular scanning configuration in a second position.

In another aspect, the bracket (30) is configured to hold the bridge device (9) in a third position where the enclosure (27) extends upward from the object approximately one hundred eighty degrees from the surface of the object to read all items on both sides of the bridge device (9) with a circularly polarized field in the configuration of a free air antenna.

In yet another aspect the bracket (30) is configured to receive opposite ends (13, 19) of the tube (10).

Another aspect further comprising one or more removable contact plates (14, 143) configured for a combination of battery sizes.

In another aspect, the device (9) includes a hall effect sensor (37).

In another aspect the enclosure (27) comprises a split molded case (99).

In another aspect a GPS (40) is disposed in the enclosure (27).

In yet another aspect of the invention, the configuration of the enclosure (27) relative to the tube (10) provides for flipping the device (9) up and down to visually differentiate the top and bottom of the resonant structure.

In another aspect of the invention the enclosure (27) extends from the tube (10) at an offset from the center line of the tube (10) to provide a whistle-shaped configuration to visually differentiate the top and bottom of the resonant structure.

Another aspect of the invention is that the tube (10) body has locking channels (11) for engagement in a base plate or clip.

In yet another aspect of the invention, the antenna (42) comprises a circularly polarized monopole microwave antenna.

### BRIEF DESCRIPTION OF THE DRAWINGS

FIG. 1 is a perspective of a first embodiment of the RF bridge device.

FIG. 2A is a cutaway perspective view showing the PCBA and antenna.

FIG. 2B is a diagram showing the layout of a printed circuit board assembly on the RF bridge device.

FIG. 3A is a perspective view of the RF bridge device in a first configuration.

FIG. 3B is a perspective view of the RF bridge device in a second configuration.

FIG. 3C is a perspective view of the RF bridge device in a third configuration.

FIG. 3D illustrates a beam formed by a single antenna.

FIG. 3E illustrates a beam formed by two radiating elements.

FIG. 3F illustrates a beam formed by four radiating elements.

FIGS. 3G-3I illustrate additional variations of beam configurations.

FIG. 4A is a perspective view of a bracket supporting the RF bridge device in a first configuration.

FIG. 4B is a perspective view of a bracket supporting the RF bridge device in a second configuration.

FIG. 4C is an enlarged perspective view of the bracket.

FIG. 4D is a perspective view of the first end of the battery tube.

FIG. 4E is a perspective view of the second end of the battery tube configured for power, signal, or data connections to a variety of devices.

FIG. 5 is a perspective view of a first embodiment of the RF bridge device of the present invention.

FIG. 6 is an exploded perspective view of the embodiment shown in FIG. 5.

FIG. 7 is an exploded perspective view of a battery tube with a plug insert.

FIG. 8 is an exploded perspective view of a battery tube subassembly.

FIG. 9 is an exploded perspective view of a battery tube plug subassembly.

FIG. 10 is a perspective view of an alternate embodiment of the RF bridge device of the present invention.

FIG. 11 is a diagrammatic view of an alternate embodiment of the RF bridge device with a plurality of receivers disposed on the outside of a round tube.

### DESCRIPTION OF THE PREFERRED EMBODIMENTS

At the outset, it should be clearly understood that like reference numerals are intended to identify the same structural elements, portions or surfaces consistently throughout the several drawing figures, as such elements, portions or surfaces may be further described or explained by the entire written specification, of which this detailed description is an integral part. Unless otherwise indicated, the drawings are intended to be read (e.g., cross-hatching, arrangement of parts, proportion, debris, etc.) together with the specification, and are to be considered a portion of the entire written description of this invention. As used in the following description, the terms “horizontal”, “vertical”, “left”, “right”, “up” and “down”, as well as adjectival and adverbial derivatives thereof, (e.g., “horizontally”, “rightwardly”, “upwardly”, etc.), simply refer to the orientation of the illustrated structure as the particular drawing figure faces the reader. Similarly, the terms “inwardly” and “outwardly” generally refer to the orientation of a surface relative to its axis of elongation, or of rotation, as appropriate.

The present invention provides a hardware platform in the form of a battery powered antenna device with a unique structure. The device may be used in combination with various systems that utilize a battery powered mobile device capable of traveling through a process while gathering and locating RF signals form a plurality of other bridges and transponders. In transit applications, the RF bridge device may be used on moving assets and or carriers for other assets. The device provides mobile locating/tracking by locating both items and other transit tags. The device may provide both sensor capability and lockout/tagout options. The device may be enhanced with a global positioning system (“GPS”) or remote versions via cellular or satellite networks. All versions have the option of being hardwired for power and implementing I/O or sensors. Cellular and satellite options may be configured as external additions to the base unit.

The device may also be used as a marker in storage locations. The device takes inventory automatically and enables and verifies pick/put/pack functions. The device can also integrate external sensors.

The device may also be used in systems for access control for use in connection with doors, gates, or for equipment control. The system reads item, transit, and marker tags as a means of granting access or reporting on movements.

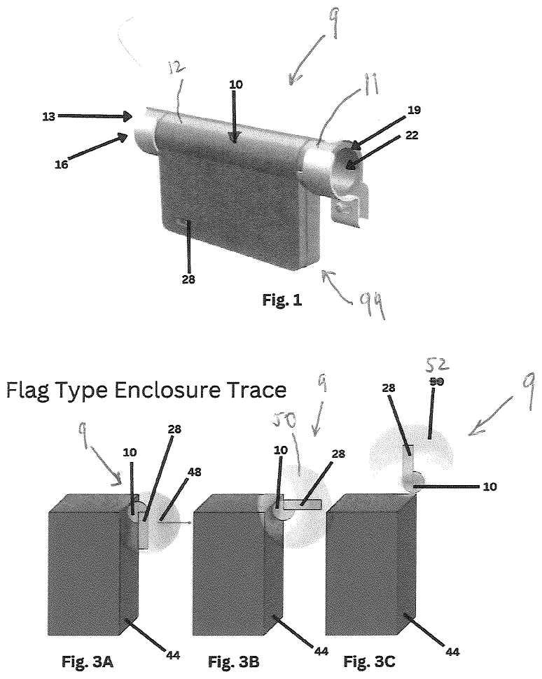

Referring now generally to FIGS. 1-4E of the drawings, and initially to FIG. 1, this invention provides a radio frequency (“RF”) bridge device 9 having a tube 10 that may be constructed from an elongate cylinder having a first end 13 with a first opening 16. A second end 19 is disposed opposite from the first end 13. The second end 19 may have a second opening 22 defined therein. The first and second openings 16 and 22 may have threads disposed therein. The tube 10 is configured to receive one or more batteries. Other shapes and sizes for tube 10 may also be suitable.

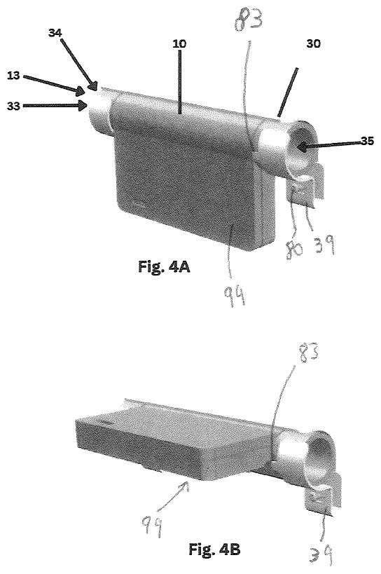

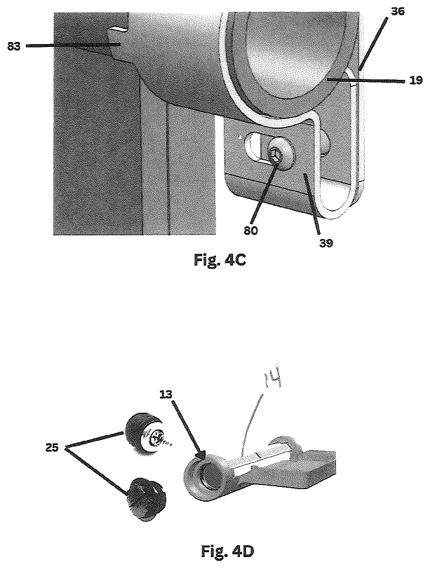

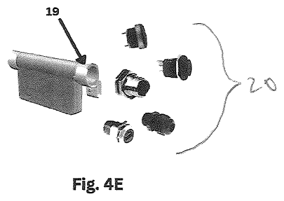

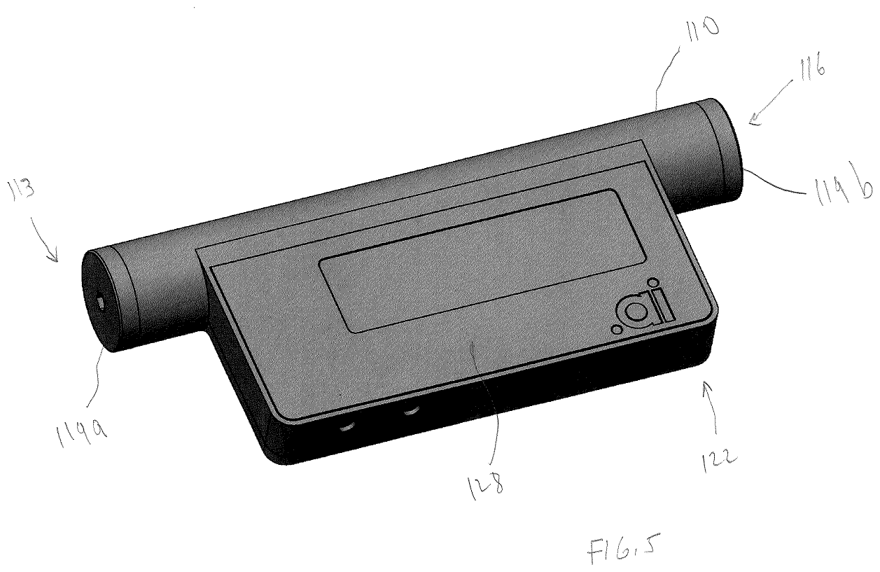

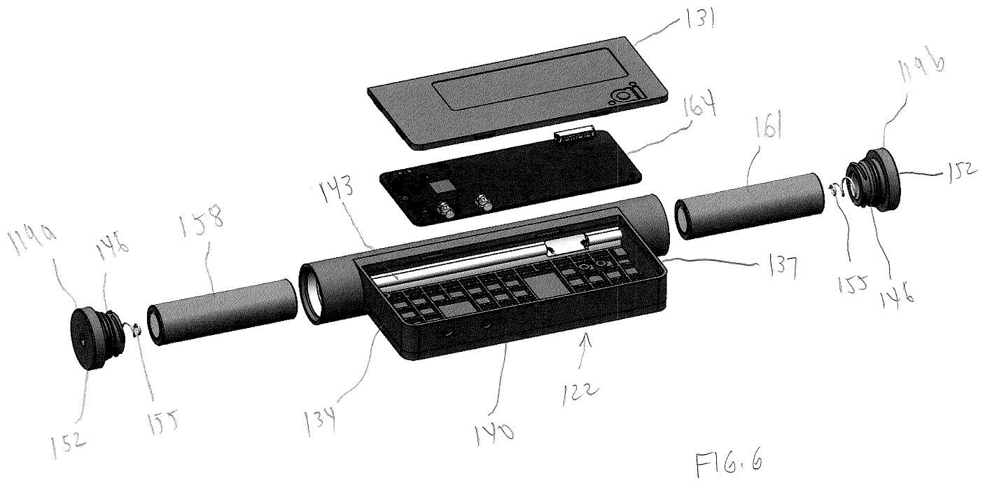

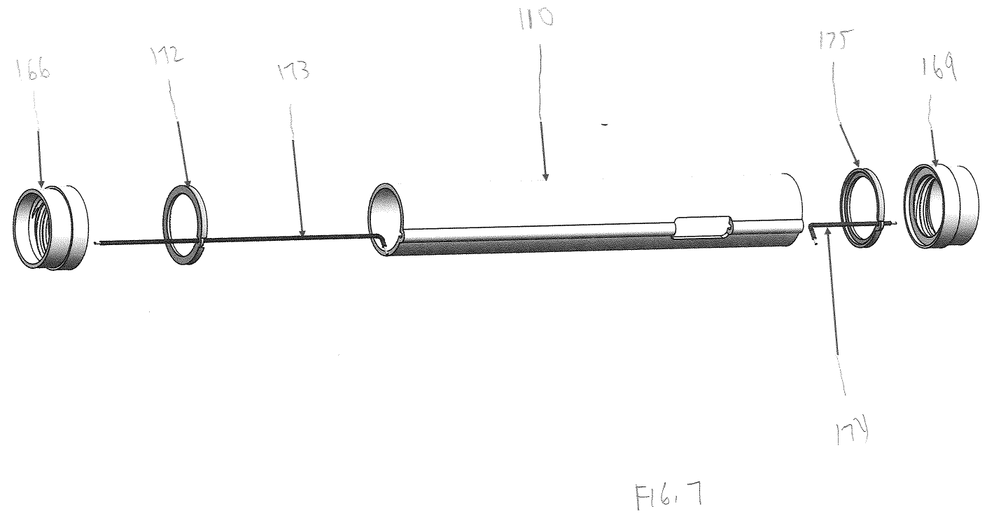

The first end 13 may be configured to receive a removable screw cap 25 (FIG. 4D). This cap 25 may be passive or may have an on/off switch function.

As shown in FIG. 4E, the second end 19 may be configured to receive any of the following devices and or connectors 20: a sealed push button, an 8 pin M12 connector (VBUS (power out), D1, D2, D3, D4 (data), (0.5V-4.5V) and GND (ground)), a sealed cable gland, a female USB port, or the like.

Returning to FIG. 1, the tube 10 provides enhanced impact protection for batteries in a plastic assembly. The tube 10 may be configured to receive various combinations of batteries including, but not limited to, combinations of a 18650 @ 18 mm×65 mm and 18350 @ 18 mm×35 mm. The batteries may provide 7-7.4 VDC. Channels formed in the body of the tube 10 enable secure placement of a dynamic contact plate 14 (FIG. 4D) to enable different battery configurations without changing the main design or construction of the RF bridge device 9.

The tube 10 may be provided with locking channels 11 for engagement in a base plate or clip. The ends 13 and 19 of the tube 10 may be configured to match the standard outside diameter of ¾″ PVC or galvanized conduit pipe or the like. Accordingly, users can mount RF bridge devices 9 with common brackets available off the shelf at hardware stores.

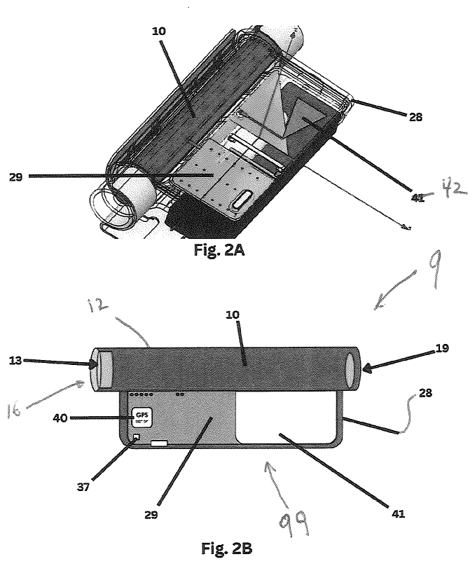

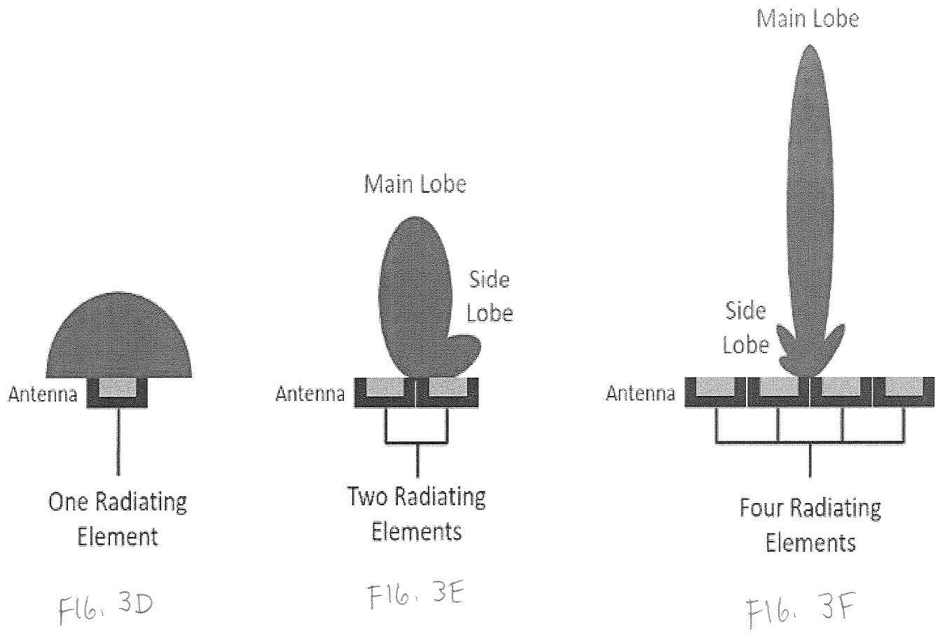

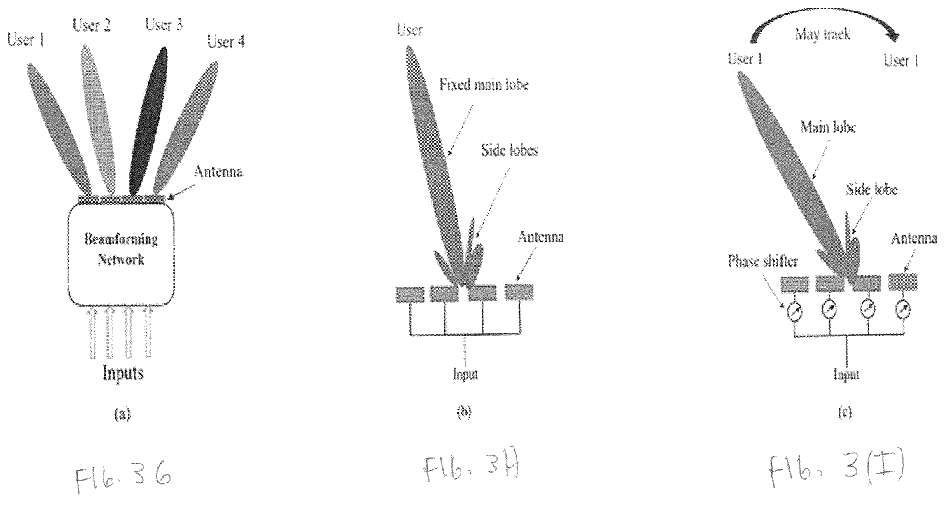

Turning to FIGS. 2A and 2B, an enclosure 27 forming a shelf 28 extends substantially perpendicular from the battery tube 10. The shelf 28 supports a printed circuit board assembly (“PCBA”) 29. The shelf 28 extends from the battery tube 10 at an offset from the center line to provide a “whistle” configuration (best shown in FIG. 3B) in cross-section. The whistle shape provides for visual differentiation of the top and bottom of the resonant structure. The PCBA 29 may include a hall effect sensor 37 to sense the orientation of the RF bridge device 9 by means of a magnetic field. The PCBA 29 may also include a global positioning system (“GPS”) 40.

The PCBA 29 also includes an area 41 for an antenna 42 (BLE and UHF) (FIG. 2A). The PCBA 29 may be suspended in a split molded plastic case 99.

The configuration of the shelf 28 relative to the battery tube 10 provides for flipping the structure up and down as a means of visually signaling operators in a process while also opitimizing directional resonance for the process.

As will be described in greater detail herein, a bracket 30 (FIG. 4A) may be designed with a locking structure to retain the RF bridge device 9 in place.

Turning to FIG. 3A, the tube 10 may be mounted with the antenna structure 41 in the shelf 28 oriented downward and parallel to a metal surface 44 creating a circularly polarized field 48 similar to a patch antenna. In this “face max read” position the antenna provides max power to the front of a shelf, fork, gate, etc.

In FIG. 3B, the tube 10 may also be mounted with the antenna structure 41 in the shelf 28 oriented at 90 degrees to the metal surface 44 creating a circularly polarized field 50 creating a “verified read” for lower power for scanning items passing above the RF bridge device 9.

Turning to FIG. 3C, the tube 10 may be mounted such that the antenna structure 41 in the shelf 28 extends 180 degrees from the metal surface 44 to read all items on both sides of the RF bridge device 9 with a circularly polarized field 52 at max power similar to a free air antenna.

The RF bridge device 9 creates an optimized elliptical radiating field in all directions.

The device 9 may incorporate two radios, enabling projection of a low frequency power wave to illuminate passive transponders via one radio while simultaneously gathering the beacons that they generate on another higher frequency radio. The microwave antenna 42 (FIG. 2A) is a circularly polarized monopole that is capable of changing the shape of the radiation pattern based on the orientation. When it is disposed against a reflective substrate, (i.e., metal) it functions as if it is a patch antenna. This configuration is a unique implementation of beam forming technology. The battery tube 10 may mechanically direct energy towards the target by means of rotation of the device 9 in the bracket 30. The convex shape of the round tube 10 provides a broader spread of the signal and fills in the hole in the “doughnut.”

Multiple antennae may be positioned around the tube to provide electrical beam forming. As shown in FIGS. 3D-3I, different shapes of beams may be formed with different configurations of antennae.

The invention provides a unique UHF stamped antenna design on the PCBA 29 that is balanced to work perpendicular to a tube 10 and optimized for linear polarization and gain regardless of orientation.

Turning to FIGS. 4A-4C, a bracket 30 may be provided with a round opening 33 at one end 34 for receiving an end 13 of the battery tube 10. The opposite side of the bracket 30 has a round opening 35 for receiving the opposite end of the battery tube 10. A first portion 36 (FIG. 4C) and a removable second portion 39 combine to form a circular channel for holding the end of the battery tube 10. The second portion 39 may be removably attached to the first portion by means of a fastener 80 that can be tightened by hand. A tooth 83 may be added to one side of the metal bracket 30 that both holds the RF bridge device 9 down when in the standard area sweep position and locks it into place in the 90-degree scanning orientation. This locking assembly is held in place with a single fastener 80 that can be loosened and tightened by hand enabling the engagement of the tooth 83 in the assembly.

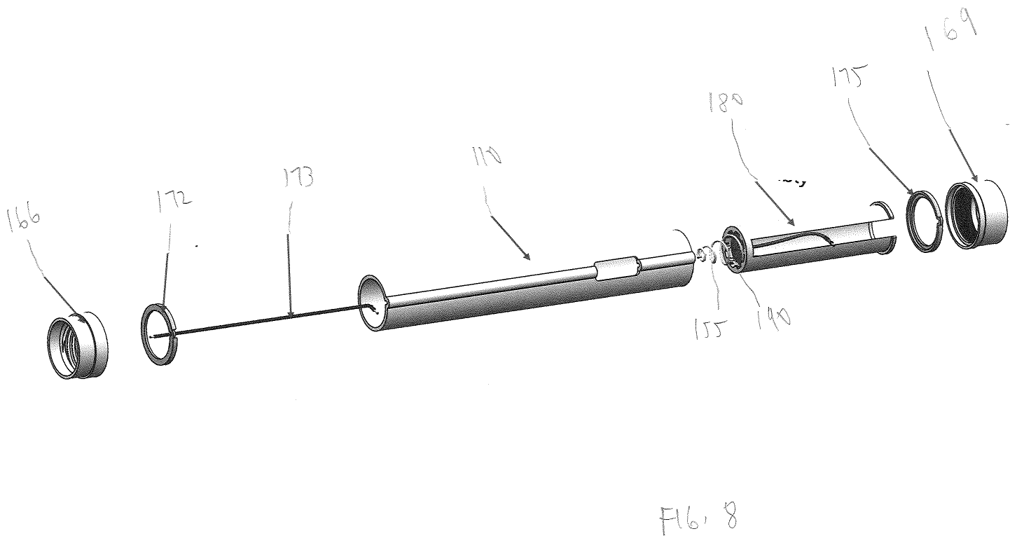

Turning to FIG. 5, in another embodiment an RF Bridge Device 100 is shown with an elongate tube 110 extending from a first end 113 to a second opposite end 116. Each end of the tube 110 may be provided with a removable cap 119a and 119b as will be described herein. An enclosure 122 forming a shelf 128 extends laterally from a line offset from the longitudinal axis of the tube 110. The ends 113 and 116 of the tube 110 may be rotatably mounted in a bracket configured for mounting on the surface of an object to be tracked.

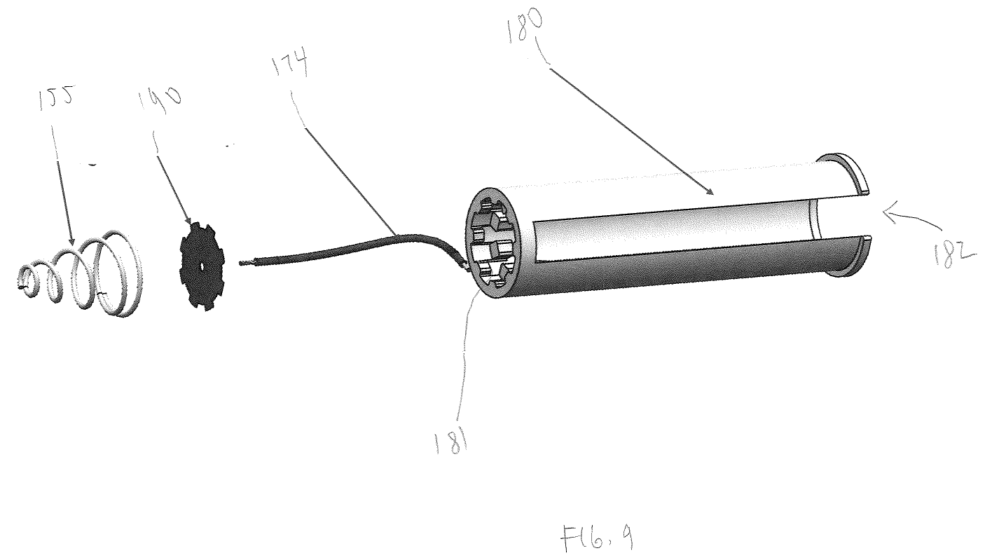

Turning to FIG. 6, the enclosure 122 may have a removable lid 131. The base of the enclosure 122 may be formed with a pair of end walls 134, 137 and a side wall 140. The side wall 140 may be disposed in spaced apart parallel relation to the longitudinal axis of tube 110. The inside of the tube 110 is shown with a contact plate 143 configured for an arrangement of batteries 158, 161 inside the tube 110. The contact plate 143 is removable such that a different contact plate may be substituted to accommodate a different battery configuration.

Removable caps 119a and 119b are shown with external threads 146 disposed on a cylindrical portion 149 adjacent to a larger diameter head 152. The external threads 146 are configured to engage with internal threads disposed at the ends of tube 110. The caps 119a and 119b may be provided with electrical contacts 155 that engage with terminals at the ends of the batteries 158 and 161.

The enclosure 122 is configured to receive a printed circuit board assembly (“PCBA”) 164. The enclosure 122 may also be configured for hall effect sensors, a GPS, and the PCBA 164 may be configured for an antenna.

Turning to FIG. 7, the tube 110 may be constructed of aluminum and may form a part of the antenna circuit. A quick thread mold insert 166 and 169 may be provided at opposite ends. Tube isolators 172 and 175 are disposed at opposite ends of the tube 110. Wires 173 and 174 may be electrically connected to various devices plugged in at either end of the tube 110.

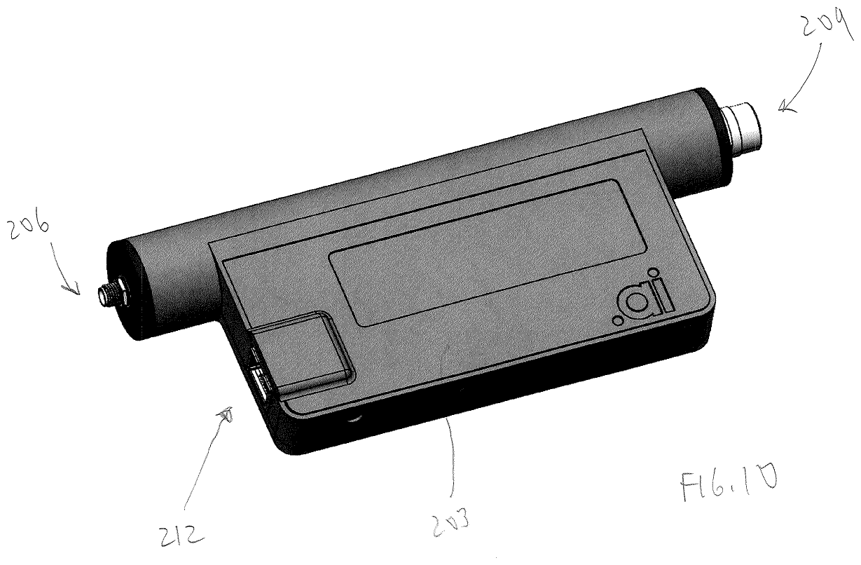

Turning to FIG. 8, an aluminum antenna tube 110 is shown with a tube spacer subassembly 180 on the right side of the figure. The subassembly 180 includes electrical connections for wire 174, connector clip 190 and electrical contact 155 in the form of a spring. The tube spacer 180 is configured to receive a battery through the second end 116.

In FIG. 9, the tube space subassembly 180 is shown in greater detail. The connector clip 190 may be mounted in one end of the subassembly 180 in a space 181 configured for receiving the clip 190. A battery slides into the open end 182 of the subassembly 180.

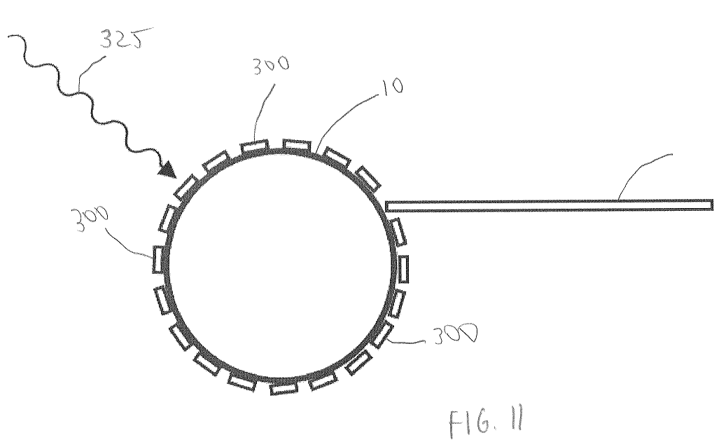

Turning to FIG. 10, in an alternate embodiment an RF bridge device 200 may incorporate Ethernet/Wifi into the device 200. The device 200 may incorporate different connectors 206, 209 and a different top cover 203 with a receptacle 212 to accommodate variations. Either end may be configured to receive various connector options including, but not limited to, a sealed push button, an 8 pin M12 connector (VBUS (power out), D1, D2, D3, D4 (data), (0.5V-4.5V) and GND (ground)), a sealed cable gland, a female USB port, or the like.

In FIG. 11, a metallic battery tube 10 may be used to provide a circular structure to mount a plurality of receivers 300 around the surface thereof. The receivers 300 may be used as a phased antenna array to determine the direction from which the radio signal is being received. The angle of arrival (“AoA”) information along with the time of flight (“ToF”) information may be used to locate other bridge devices and transponders more precisely in an application.

The present invention provides a battery tube design with many improved features. The invention provides enhanced impact protection for batteries in a plastic assembly. The device also provides contact stop repositioning for varying battery configurations. The device includes wiring chases for optional accessory configurations. The shelf supports a printed circuit board assembly (PCBA). A “whistle” shape is employed to visually differentiate top/bottom of resonant structure.

The device also has the ability to flip the structure up and down as a means of visually signaling operators in a process, while also optimizing directional RF resonance for the process.

The device provides for the use of interchangeable end caps, connectors, or devices to enable differing configurations and optional features.

Locking channels in the tube body are configured for engagement in a base plate or clip.

The present invention includes a design of a base plate with a locking clip to retain the device in place.

The device provides for sensing the device orientation by means of a magnetic field (Hall-Effect Switch).

A unique, circularly polarized monopole microwave antenna, capable of changing the shape of the radiation pattern based on the orientation, is designed for: a battery tube on one side of the structure, mounting with structure parallel to a metal surface, mounting at 90 degrees to metal surface, or mounting at 180 degrees to metal surface.

The system also provides a unique UHF stamped antenna design balanced to work perpendicular to a battery tube for optimized linear polarization and gain regardless of orientation.

The present invention contemplates that many changes and modifications may be made. Therefore, while the presently-preferred form of the RF bridge device has been shown and described, and several modifications and alternatives discussed, persons skilled in this art will readily appreciate that various additional changes and modifications may be made without departing from the spirit of the invention, as defined and differentiated by the following claims.

What is claimed is:

1. A radio frequency bridge device for use with an object to be tracked, the bridge device comprising:
a tube configured to receive one or more batteries, the tube having a first opening at a first end and a second opening at a second end disposed opposite from the first end, the tube having a body portion with an outer wall;
an enclosure extending outward from the outer wall of the tube;
a printed circuit board assembly mounted in the enclosure;
an antenna disposed on the printed circuit board assembly;
a bracket configured to mount to a surface of the object to be tracked, the bracket configured such that the tube rotates inside the bracket between a first position and a second position; and,
wherein in the first position a surface on the enclosure is oriented parallel and facing the surface of the object and in a second position the enclosure is disposed substantially perpendicular to the surface of the object.

2. The device of claim 1, wherein the bracket further comprises a tooth that is configured to hold the bridge device down relative to the surface of the object in a standard area sweep positions in a first position and is configured to hold the bridge device in a perpendicular scanning configuration in a second position.

3. The device of claim 1, wherein the bracket is configured to hold the bridge device in a third position where the enclosure extends upward from the object approximately one hundred eighty degrees from the surface of the object to read all items on both sides of the bridge device with a circularly polarized field in the configuration of a free air antenna.

4. The device of claim 1, wherein the bracket is configured to receive opposite ends of the tube.

5. The device of claim 1, further comprising two or more radios, enabling projection of a low frequency power wave to illuminate passive transponders via one radio while simultaneously gathering the beacons that they generate on another higher frequency radio.

6. The device of claim 1, further comprising one or more removable contact plates configured for a combination of battery sizes.

7. The device of claim 1, further comprising a hall effect sensor.

8. The device of claim 1, wherein one of the first and second ends of the tube is configured with power, signal or data connections.

9. The device of claim 1, further comprising a GPS disposed in the enclosure.

10. The device of claim 1, wherein the configuration of the enclosure relative to the tube provides for flipping the structure up and down to visually differentiate the top and bottom of the resonant structure.

11. The device of claim 1, wherein the enclosure extends from the tube at an offset from the center line of the tube to provide a whistle-shaped configuration to visually differentiate the top and bottom of the resonant structure.

12. The device of claim 1, wherein the tube body has a plurality of receivers disposed thereon configured for detecting the angle from which a radio signal is being received.

13. The device of claim 1, wherein the antenna comprises a circularly polarized monopole microwave antenna.

14. A radio frequency bridge device for use with an object to be tracked, the bridge device comprising:
a tube having a longitudinal axis, the tube configured to receive one or more batteries, the tube having a first opening at a first end and a second opening at a second end disposed opposite from the first end, the tube having a body portion with an outer wall;
an enclosure extending outward from the outer wall of the tube, the enclosure extending from the outer wall of the tube at a position offset from the longitudinal axis of the tube;
a printed circuit board assembly mounted in the enclosure;
an antenna disposed on the printed circuit board assembly;
a bracket configured to mount to a surface of the object to be tracked, the bracket configured such that the tube rotates inside the bracket between a first position and a second position;
a tooth extending from the bracket, the tooth configured to hold the enclosure in one of the first and the second position; and,
wherein in the first position a surface of the enclosure is oriented parallel and facing the surface of the object and in a second position the enclosure is disposed substantially perpendicular to the surface of the object.

15. The device of claim 14, wherein the bracket further comprises a tooth that is configured to hold the bridge device down relative to the surface of the object in a standard area sweep positions in a first position and is configured to hold the bridge device in a perpendicular scanning configuration in a second position.

16. The device of claim 14, wherein the bracket is configured to hold the bridge device in a third position where the enclosure extends upward from the object approximately one hundred eighty degrees from the surface of the object to read all items on both sides of the bridge device with a circularly polarized field in the configuration of a free air antenna.

17. The device of claim 14, wherein one of the first and second ends of the tube is configured with power, signal or data connections.

18. The device of claim 14, further comprising two or more radios, enabling projection of a low frequency power wave to illuminate passive transponders via one radio while simultaneously gathering the beacons that they generate on another higher frequency radio.

19. The device of claim 14, further comprising one or more removable contact plates configured for a combination of battery sizes.

20. The device of claim 14, wherein the tube body has a plurality of receivers disposed thereon configured for detecting the angle from which a radio signal is being received.

21. A radio frequency bridge device for use with an object to be tracked, the bridge device comprising:
a hollow cylindrical tube configured to receive one or more batteries, the tube having a first opening at a first end and a second opening at a second end disposed opposite from the first end, the tube having a body portion with an outer wall;
an enclosure extending outward from the outer wall of the tube;
a printed circuit board assembly mounted in the enclosure;
an antenna disposed on the printed circuit board assembly;
a bracket configured to mount to the surface of the object to be tracked, the bracket configured to receive opposite ends of the tube such that the tube rotates inside the bracket between a first position, a second position, and a third position;
wherein one of the first and second ends of the tube is configured with power, signal or data connections;
wherein in the first position a bottom surface of the enclosure is oriented parallel and facing the surface of the object and in a second position the enclosure is disposed substantially perpendicular to the surface of the object; and,
wherein in the third position the enclosure extends upward from the object approximately one hundred eighty degrees from the surface of the object to read all items on both sides of the bridge device with a circularly polarized field in the configuration of a free air antenna.

22. The device of claim 21, wherein the tube body has a plurality of receivers disposed thereon configured for detecting the angle from which a radio signal is being received.
